(19) United States
(12) Patent Application Publication
(10) Pub. No.: US 2017/0323863 A1
(43) Pub. Date: Nov. 9, 2017

(54) SEMICONDUCTOR DEVICE AND MANUFACTURING METHOD THEREOF

(71) Applicant: Amkor Technology, Inc., Tempe, AZ (US)

(72) Inventors: Kyoung Yeon Lee, Seoul (KR); Tae Yong Lee, Goyang-si (KR); Min Chul Shin, Bucheon-si (KR); Se Man Oh, Seoul (KR)

(21) Appl. No.: 15/150,342

(22) Filed: May 9, 2016

(51) Int. Cl. H01L 23/00

(52) U.S. Cl. CPC H01L 24/11; H01L 24/81; H01L 24/16; H01L 2224/16238; H01L 2224/16104; H01L 2224/16057; H01L 2224/1147; H01L 2224/1146; H01L 2224/1111; H01L 2224/81359; H01L 2224/81379; H01L 2224/16012

(57) ABSTRACT

A semiconductor device and a method of manufacturing a semiconductor device. As a non-limiting example, various aspects of this disclosure provide a semiconductor device, and a method of manufacturing thereof, that comprises a substrate including a dielectric layer, at least one conductive trace and conductive bump pad formed on one surface of the dielectric layer, and a protection layer covering the at least one conductive trace and conductive bump pad, the at least one conductive bump pad having one end exposed through the protection layer, and a semiconductor die electrically connected to the conductive bump pad of the substrate.

### BACKGROUND

Present semiconductor devices and methods for manufacturing semiconductor devices are inadequate, for example resulting in too-low sensitivity, excess cost, decreased reliability, or package sizes that are too large. Further limitations and disadvantages of conventional and traditional approaches will become apparent to one of skill in the art, through comparison of such approaches with the present disclosure as set forth in the remainder of the present application with reference to the drawings.

### BRIEF DESCRIPTION OF SEVERAL VIEWS OF THE DRAWINGS

FIG. 1 is a cross-sectional view of a semiconductor device according to various embodiments of the present disclosure.

FIGS. 2A and 2B are plan views of some regions of a substrate in a semiconductor device according to various embodiments of the present disclosure.

FIGS. 3A and 3B are cross-sectional views of substrates in a semiconductor device according to various embodiments of the present disclosure.

FIGS. 4A to 4H are cross-sectional views of a manufacturing method of a semiconductor device according to various embodiments of the present disclosure.

### SUMMARY

Various aspects of this disclosure provide a semiconductor device and a method of manufacturing a semiconductor device. As a non-limiting example, various aspects of this disclosure provide a semiconductor device, and a method of manufacturing thereof, that comprises a substrate including a dielectric layer, at least one conductive trace and conductive bump pad formed on one surface of the dielectric layer, and a protection layer covering the at least one conductive trace and conductive bump pad, the at least one conductive bump pad having one end exposed through the protection layer, and a semiconductor die electrically connected to the conductive bump pad of the substrate.

### DETAILED DESCRIPTION OF VARIOUS ASPECTS OF THE DISCLOSURE

The following discussion presents various aspects of the present disclosure by providing examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.”

The terminology used herein is for the purpose of describing particular examples only and is not intended to be limiting of the disclosure. As used herein, the singular forms are intended to include the plural forms as well, unless the context clearly indicates otherwise. It will be further understood that the terms “comprises,” “includes,” “comprising,” “including,” “has,” “have,” “having,” and the like when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure. Similarly, various spatial terms, such as “upper,” “above,” “lower,” “below,” “side,” “lateral,” “horizontal,” “vertical,” and the like, may be used in distinguishing one element from another element in a relative manner. It should be understood, however, that components may be oriented in different manners, for example a semiconductor device may be turned sideways so that its “top” surface is facing horizontally and its “side” surface is facing vertically, without departing from the teachings of the present disclosure.

It will also be understood that terms coupled, connected, attached, and the like include both direct and indirect (e.g., with an intervening element) coupling, connecting, attaching, etc., unless explicitly indicated otherwise. For example, if element A is coupled to element B, element A may be indirectly coupled to element B through an intermediate signal distribution structure, element A may be directly coupled to element B (e.g., adhered directly to, soldered directly to, attached by direct metal-to-metal bond, etc.), etc.

In the drawings, the dimensions of structures, layers, regions, etc. (e.g., absolute and/or relative dimensions) may be exaggerated for clarity. While such dimensions are generally indicative of an example implementation, they are not limiting. For example, if structure A is illustrated as being larger than region B, this is generally indicative of an example implementation, but structure A is generally not required to be larger than structure B, unless otherwise indicated. Additionally, in the drawings, like reference numerals may refer to like elements throughout the discussion.

Various embodiments of the disclosure relate to a semiconductor device and a manufacturing method thereof.

In general, a substrate for a semiconductor functions to electrically connect a semiconductor die and an external device (for example, a main board, a mother board, etc.). Unlike general components, such as a capacitor, a resistor, or the like, a semiconductor component mounted in a very high integration level might not be able to be directly mounted in an external device. Therefore, in order to transmit an electrical signal of the semiconductor component to the external device, a substrate for use in a semiconductor is may be utilized.

According to an aspect of the present disclosure, there is provided a semiconductor device including a substrate including a dielectric layer, at least one conductive trace and conductive bump pad formed on one surface of the dielectric layer, and a protection layer covering the at least one conductive trace and conductive bump pad, the at least one conductive bump pad having one end exposed through the protection layer, and a semiconductor die electrically connected to the conductive bump pad of the substrate.

According to another aspect of the present disclosure, there is provided a semiconductor device including a substrate including at least one conductive trace and conductive bump pad and a protection layer covering the at least one conductive trace and conductive bump pad, the at least one conductive bump pad having one end exposed through the protection layer, a semiconductor die electrically connected to the conductive bump pad of the substrate, and an encapsulant interposed between the substrate and the semiconductor die.

According to another aspect of the present disclosure, there is provided a manufacturing method of a semiconductor device, the manufacturing method including coating a photoresist resin on a dielectric layer and then performing photolithography and developing processes to form at least one trace opening and bump pad opening in the photoresist resin, performing a plating process on the trace opening and the bump pad opening to form a conductive trace and a conductive bump pad on the trace opening and the bump pad opening, respectively, filling the trace opening with a photoresist resin and performing an additional plating process on the bump pad opening to form a conductive bump pad having a larger thickness than the conductive traces, and removing the photoresist resin and covering the conductive trace and the conductive bump pad with a protection layer, the conductive bump pad having one end exposed through the protection layer.

As described above, according to various embodiments of the present disclosure, since non-exposed conductive traces are formed between exposed and/or protruded conductive bump pads, electrical shorts between the conductive bump pads and the conductive traces may not occur even if spaces between the conductive bump pads and the conductive traces are reduced.

In addition, according to various embodiments of the present disclosure, since heights (thicknesses) of the conductive bump pads may be adjusted, a gap or space between the semiconductor die and the substrate can be adjusted.

Moreover, according to various embodiments of the present disclosure, since at least one line of conductive traces are inserted between spaces of normal conductive bump pads, improved design flexibility can be achieved, compared to the prior art.

Various aspects of the present disclosure will now be described with regard to a process for forming the conductive trace and the conductive bump pad mainly using a plating process, but aspects of the present disclosure are not limited thereto. The conductive trace and/or the conductive bump pad disclosed in the present disclosure may, however, be formed by any of a variety of processes (e.g., spin coating, printing, spray coating, sintering, thermal oxidation, physical vapor deposition (PVD), sputtering, chemical vapor deposition (CVD), atomic layer deposition (ALD), or the like).

In addition, various aspects of the present disclosure will be described mainly with regard to a case where the conductive trace and the conductive bump pad are made of copper. The conductive trace and/or the conductive bump pad disclosed in the present disclosure may, however, be formed by any of a variety of materials (e.g., gold, silver, nickel, palladium, aluminum, or the like).

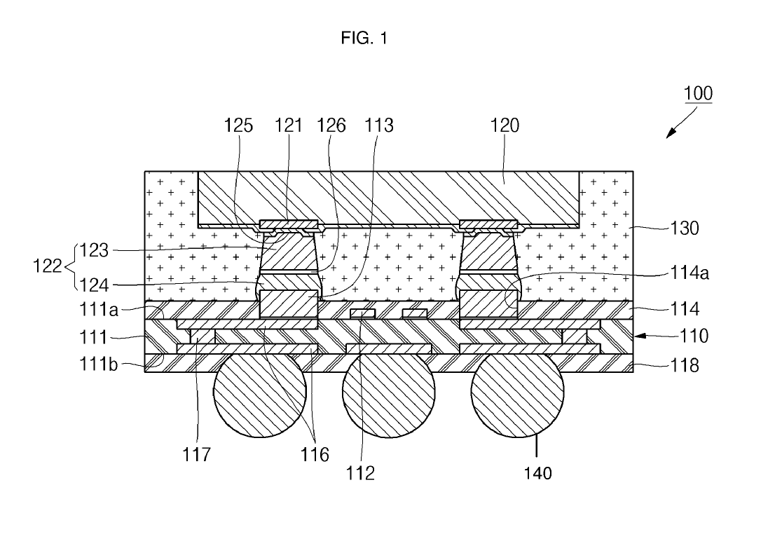

Referring to FIG. 1, a cross-sectional view of a semiconductor device (100) according to various embodiments of the present disclosure is illustrated.

As illustrated in FIG. 1, the semiconductor device 100 according to various embodiments of the present disclosure may include a substrate 110, a semiconductor die 120 and an encapsulation member 130. In addition, the semiconductor device 100 according to various embodiments of the present disclosure may further include a conductive bump 140 connected to the substrate 110.

The substrate 110 includes a dielectric layer (e.g. insulation layer) 111, at least one conductive trace 112, at least one conductive bump pad 113, and at least one protection layer 114.

The dielectric layer 111 has a substantially planar first surface 111a and a substantially planar second surface 111b opposite to the first surface 111a. The dielectric layer 111 may include, for example, one of a thermocurable resin, thermoplastic resin, silicon, glass, ceramic and equivalents thereof, but aspects of the present disclosure are not limited thereto. In addition, the dielectric layer 111 may be rigid or flexible, but aspects of the present disclosure are not limited thereto.

The at least one conductive trace 112 is formed on the first surface 111a of the dielectric layer 111. The conductive trace 112 may become a path for an electrical signal (e.g., an electrical signal, a ground signal and/or a power signal, and so on, passing between the semiconductor die 120 and an external device).

The conductive traces 112 may be formed within the dielectric layer 111 as well as on the first surface 111a of the dielectric layer 111. Here, the conductive trace 112 may also be formed on the second surface 111b of the dielectric layer 111. For the sake of convenient explanation, the conductive traces formed within the dielectric layer 111 and on the second surface 111b of the dielectric layer 111 may be defined as second conductive traces 116. In addition, since a conductive via 117 is formed passing through the dielectric layer 111, the conductive traces 112 and 116 formed on the dielectric layer 111, within the dielectric layer 111 and under the dielectric layer 111 may be electrically connected to one another. In the present disclosure, the description will generally focus on the conductive trace 112 formed on the first surface 111a of the dielectric layer 111.

Meanwhile, the conductive trace 112 may include, for example, one or more of copper, gold, silver, nickel, palladium, aluminum, alloys thereof and equivalents thereof, but aspects of the present disclosure are not limited thereto.

The at least one conductive bump pad 113 is formed on the first surface 111a of the dielectric layer 111. That is to say, the conductive bump pad 113 is formed to be spaced a predetermined distance apart from the conductive trace 112. The semiconductor die 120 is electrically connected to the conductive bump pad 113. The conductive bump pad 113 may include, for example, one or more of copper, gold, silver, nickel, palladium, aluminum, alloys thereof and equivalents thereof, but aspects of the present disclosure are not limited thereto. For the purpose of facilitating the manufacturing process, the conductive bump pad 113 and the conductive trace 112 may be formed using the same material (or at least one layer of the same material), but this is not necessary.

Meanwhile, the conductive bump pad 113 may be formed to have a larger width (or diameter) than the conductive trace 112. In addition, the conductive bump pad 113 may also be formed to have a larger thickness (or height) than the conductive trace 112. In addition, a space (or pitch) between the conductive bump pad 113 and the conductive trace 112 (or between center lines thereof) may be in the range of approximately 1 μm to approximately 15 μm, preferably in the range of approximately 5 μm to approximately 10 μm. That is to say, in the present disclosure, even when the space between the conductive bump pad 113 and the conductive trace 112 is in the range of approximately 1 μm to approximately 15 μm, or in the range of approximately 5 μm to approximately 10 μm, an electrical short between the conductive bump pad 113 and the conductive trace 112 may not occur.

The protection layer 114 (or dielectric layer) is formed on the first surface 111a of the dielectric layer 111 and covers the conductive trace 112 and the conductive bump pad 113. For example, the protection layer 114 allows a top surface of the conductive bump pad 113 to be exposed or protruded while entirely covering the conductive trace 112.

In addition, the protection layer 114 includes an opening 114a exposing the conductive bump pad 113, and the opening 114a and the conductive bump pad 113 may have substantially the same width (or diameter). In addition, the protection layer 114 may be formed to have a roughly planar top surface. The protection layer 114 may be formed by any of a variety of materials, for example, inorganic materials, such as a nitride (Si3N4), an oxide (SiO2) or an oxynitride (SiON) and/or organic materials, such as polyimide (PI), benzocyclobutane (BCB), polybenzooxazole (PBO), bismaleimide (BT), a phenol resin, an epoxy, or the like, but aspects of the present disclosure are not limited thereto.

As described above, in the present disclosure, the conductive trace 112 is entirely covered by the protection layer 114 and the top surface of the conductive bump pad 113 is exposed and/or protruded to the outside through the protection layer 114. Accordingly, even if the space or distance between the conductive trace 112 and the conductive bump pad 113 is relatively small, an electrical short between the conductive trace 112 and the conductive bump pad 113 is unlikely to occur.

Therefore, in the present disclosure, the substrate 110 or the semiconductor device 100 may have a further reduced size. In order to avoid an electrical short between the conductive trace 112 and the conductive bump pad 113, the space between the conductive trace 112 and the conductive bump pad 113 was previously generally set to be approximately 15 μm or greater. According to the present disclosure, however, even if the space between the conductive trace 112 and the conductive bump pad 113 is smaller than such spacing, the conductive trace 112 and the conductive bump pad 113 (or at least side portions thereof) are entirely covered by the protection layer 114, the electrical short between the conductive trace 112 and the conductive bump pad 113 can be efficiently prevented. For example, the protection layer 114 electrically isolates the conductive bump pad 113 from the conductive trace 112.

Moreover, if the size of the substrate 110 or the semiconductor device 100 is not reduced by the feature of the present disclosure, more conductive traces 112 than in the prior art are formed between, for example, two conductive bump pads 113, thereby improving the integration level of traces. Also for example, size reduction and increased trace integration level may simultaneously be achieved.

The semiconductor die 120 is electrically connected to the substrate 110 through the conductive bump 122. The semiconductor die 120 may include, for example, a bond pad 121 and a conductive bump 122 connected to the bond pad 121. Here, the concept of the bond pad 121 may encompass a conductive pad connected to a redistribution layer.

Practically, the conductive bump 122 is electrically connected to the conductive bump pad 113 of the substrate 110. Here, the conductive bump 122 may include a conductive pillar 123 (or conductive post) connected to the bond pad 121, and a solder 124 formed at a bottom end of the conductive pillar 123. Practically, the solder 124 may be connected to the conductive bump pad 113 of the substrate 110. For example, the solder 124 may cover the top surface and/or side surfaces of the conductive bump pad 113. In addition, the solder 124 may be brought into direct contact with the protection layer 114. The conductive pillar 123 may include, for example, copper, but aspects of the present disclosure are not limited thereto. Moreover, in some instances, the conductive pillar 123 may be directly electrically connected to the conductive bump pad 113. That is to say, the conductive pillar 123 and the conductive bump pad 113 may directly establish direct metal-to-metal bonding (e.g., without solder, epoxy, etc.).

In the present disclosure, since the thickness (or height) of the conductive bump 122 is sufficiently adjusted through processing control, it is easy to control a gap between the substrate 110 and the semiconductor die 120. That is to say, when the gap between the substrate 110 and the semiconductor die 120 should be relatively large, the conductive bump 122 is formed to have a relatively large thickness (or height). Conversely, when the gap between the substrate 110 and the semiconductor die 120 should be relatively small, the conductive bump 122 is formed to have a relatively small thickness (or height).

Optionally, an under bump metal 125 (e.g., gold, silver, nickel, palladium, aluminum, or alloys thereof, etc.) may be formed between the bond pad 121 and the conductive pillar 123 of the semiconductor die 120. When necessary, another under bump metal 126 may further be formed between the conductive pillar 123 and the solder 124.

The semiconductor die 120 may comprise electrical circuitry such as central processing units (CPUs), digital signal processors (DSPs), network processors, power management units, audio processors, RF circuitry, wireless baseband system-on-chip (SoC) processors, sensors, and application specific integrated circuits, for example.

The encapsulation member 130 covers the semiconductor die 120 disposed on the substrate 110. When the encapsulation member 130 (e.g., a filler thereof) has a sufficiently smaller size than the gap between the substrate 110 and the semiconductor die 120, it may fill the gap between the substrate 110 and the semiconductor die 120. In some instances, the encapsulation member 130 may entirely cover the top surface and side surfaces of the semiconductor die 120.

In addition, the top surface of the encapsulation member 130 may be coplanar with the top surface of the semiconductor die 120. That is to say, the top surface of the semiconductor die 120 may be exposed to the outside through the top surface of the encapsulation member 130. Moreover, side surfaces of the encapsulation member 130 may be coplanar with side surfaces of the substrate 110. Also for example, the side surfaces of the encapsulation member 130 may not be coplanar with the side surfaces of the substrate 110. In some instances, the encapsulation member 130 may cover the side surfaces of the substrate 110.

In addition, the gap between the substrate 110 and the semiconductor die 120 may filled with an underfill in advance of encapsulating, followed by encapsulating the semiconductor die 120 with the encapsulation member 130. The encapsulation member 130 may include, for example, an epoxy molding compound, an epoxy resin molding compound and equivalents thereof, but aspects of the present disclosure are not limited thereto.

The conductive bump 140 may be electrically connected to the bottom surface of the substrate 110. For example, the conductive bump 140 may be connected to the second conductive trace 116 and the conductive bump 140 may, in turn, be mounted to an external device. The conductive bump 140 may include, for example, one of an eutectic solder (Sn37Pb), a high lead solder (Sn95Pb), and a lead-free solder (SnAg, SnAu, SnCu, SnZn, SnZnBi, SnAgCu, SnAgBi, etc.), and equivalents thereof, but aspects of the present disclosure are not limited thereto.

The conductive bump 140 may be in the form of a flat land, or a ball, as illustrated in FIG. 1.

As described above, in the semiconductor device 100 according to various embodiments of the present disclosure, since the non-exposed conductive traces 112 are formed between exposed and/or protruded conductive bump pads 113, electrical shorts between the conductive bump pads 113 and the conductive traces 112 may not occur even if spaces between the conductive bump pads 113 and the conductive traces 112 are reduced.

In addition, in the semiconductor device 100 according to various embodiments of the present disclosure, since heights (thicknesses) of the conductive bump pads 113 are easily adjusted, a gap or space between the semiconductor die 120 and the substrate 110 can be easily adjusted. Moreover, in the semiconductor device 100 according to various embodiments of the present disclosure, since at least one line of conductive traces 112 are inserted between spaces of normal conductive bump pads 113, improved design flexibility can be achieved.

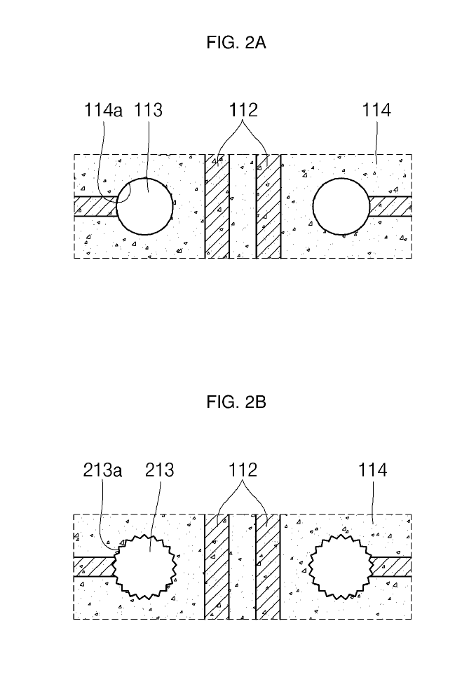

Referring to FIGS. 2A and 2B, plan views of some regions of a substrate (110) in a semiconductor device (100) according to various embodiments of the present disclosure are illustrated.

As illustrated in FIG. 2A, the conductive bump pad 113 may be shaped of a substantially circular plane (e.g., cylinder-shaped), but aspects of the present disclosure are not limited thereto. That is to say, the conductive bump pad 113 may take various plane (or planar cross-section) shapes, including, for example, an oval shape, a square shape, a rectangular shape, a pentagonal shape, a trapezoidal shape, and so on. Here, a width (diameter or size) of the opening 114a formed in the protection layer 114 may be equal to that of the conductive bump pad 113.

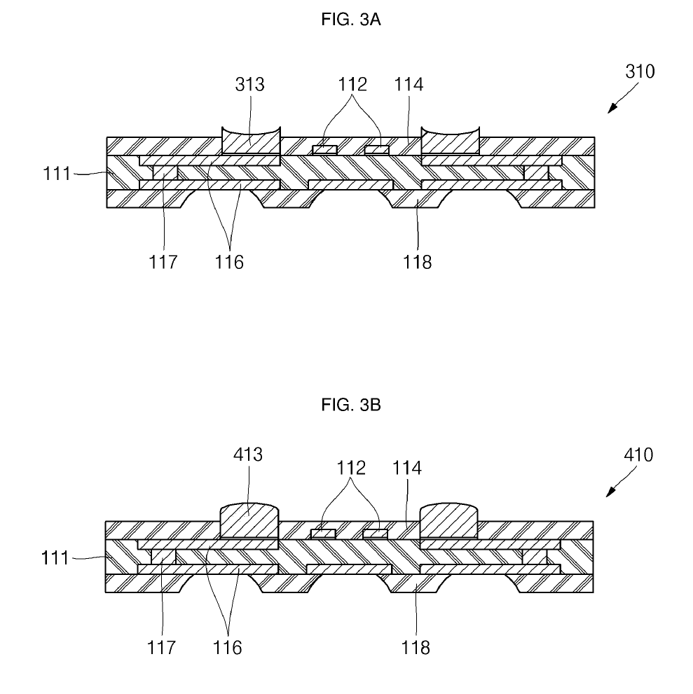

As illustrated in FIG. 2B, the conductive bump pad 213 may be shaped of a substantially circular plane and a plurality of trigonal (or triangular) protrusions 213a may further be formed along the periphery of the conductive bump pad 213, but aspects of the present disclosure are not limited thereto. That is to say, the protrusions 213a may take various plane (or planar cross-section) shapes, including, for example, a rectangular shape, a convex shape, a concave shape, and so on. Features of the conductive bump pad 213 illustrated in FIG. 2B may also be applied to conductive bump pads illustrated in FIGS. 3A and 3B or any conductive bump pad disclosed herein.

The design of the conductive bump pad 213 having various plane shapes may further improve a coupling force between the semiconductor die 120 and the conductive bump pad 213. That is to say, since the conductive bump 122 (i.e., the solder 124) formed in the semiconductor die 120 surrounds not only a top surface of the conductive bump pad 213 but side surfaces of the conductive bump pad 213 and the conductive bump pad 213 is formed to have bumpy side surfaces, a contact area between the conductive bump 122 and the conductive bump pad 213 may be increased.

Referring to FIGS. 3A and 3B, cross-sectional views of substrates (310, 410) in a semiconductor device (100) according to various embodiments of the present disclosure are illustrated.

As illustrated in FIG. 3A, a conductive bump pad 313 may have a substantially concave top portion. That is to say, the conductive bump pad 313 may be shaped of a concave lens having the largest depth at the center of its top surface and gradually decreasing depths away from the center. With this configuration, in the present disclosure, a conductive pillar 123 of a semiconductor die 120 may be directly electrically connected to the conductive bump pad 313 without assistance of a solder 124, which may not suggest that the present disclosure precludes the use of the solder 124. Metal-to-metal bonding between the semiconductor die 120 and the substrate 110 may be enabled by, for example, thermal compression. If the conductive bump pad 313 has a substantially concave top portion, a conductive bump 122 or the conductive pillar 123 preferably has a substantially convex bottom portion.

The conductive bump pad 313 having a concave top surface may be formed by, for example, varying concentrations of a plating solution during plating. For example, the concave top surface of the conductive bump pad 313 can be attained by gradually reducing the concentrations of the plating solution from a time when a height of the conductive bump pad 313 becomes approximately 80% to approximately 90% of the overall height of the conductive bump pad 313.

Conversely, as illustrated in FIG. 3B, a conductive bump pad 413 may have a substantially convex top portion. That is to say, the conductive bump pad 413 may be shaped of a convex lens having the largest height at the center of its top surface and gradually decreasing heights away from the center. With this configuration, in the present disclosure, a contact area between a conductive bump 122 of the semiconductor die 120 and the conductive bump pad 413 of a substrate 110 can be increased.

If the conductive bump pad 413 has a substantially convex top portion, the conductive bump 122 or the conductive pillar 123 preferably has a substantially concave bottom portion.

The conductive bump pad 413 having a concave bottom surface may be formed by, for example, varying concentrations of a plating solution during plating. For example, the convex bottom surface of the conductive bump pad 413 can be attained by gradually reducing the concentrations of the plating solution from a time when the height of the conductive bump pad 413 becomes approximately 80% to approximately 90% of the overall height of the conductive bump pad 413.

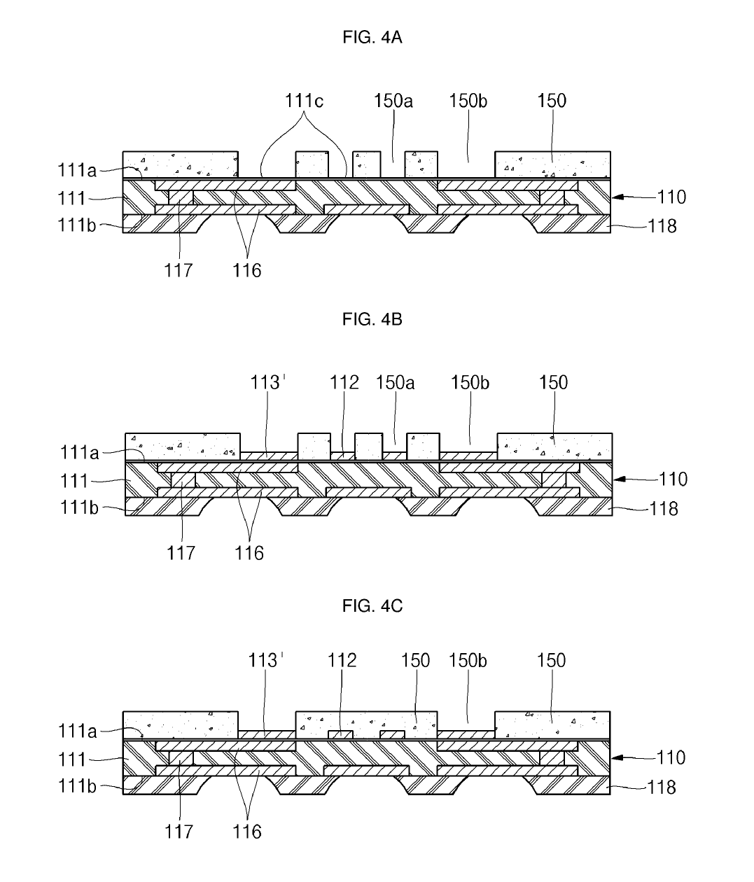

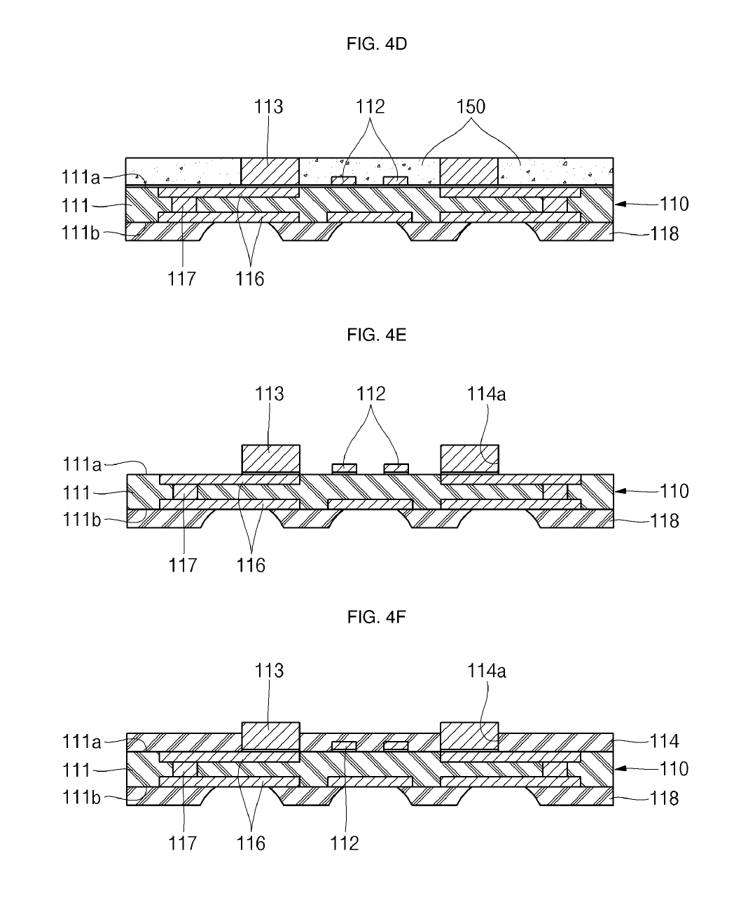

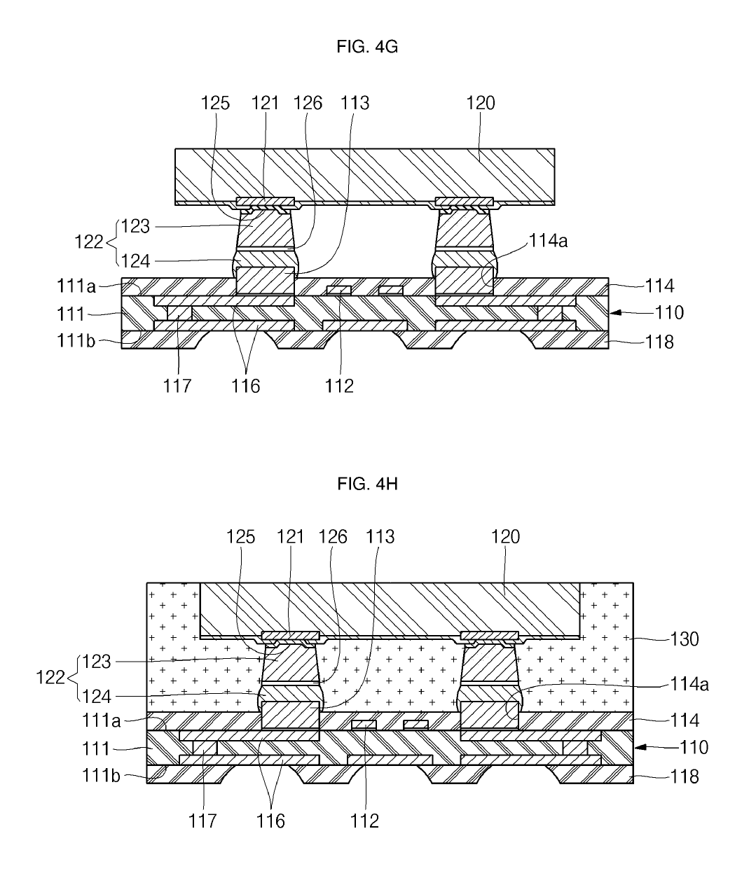

Referring to FIGS. 4A to 4H, cross-sectional views of a manufacturing method of a semiconductor device (100) according to various embodiments of the present disclosure are illustrated. It is assumed that a basic configuration of the substrate 110 is completed and the following description will focus on the process of forming the conductive trace 112 and the conductive bump pad 113 according to the present disclosure.

As illustrated in FIG. 4A, a seed layer 111c made of tungsten, titanium tungsten and/or copper (or any of a variety of materials) is formed on a first surface 111 and a photoresist resin 150 (or other masking material) is coated on the seed layer 111c, followed by forming a trace opening 150a and a bump pad opening 150b in the photoresist resin 150, for example by photolithography and developing processes. Here, the trace opening 150a may be shaped of, for example, a line, but aspects of the present disclosure are not limited thereto. In addition, the bump pad opening 150b may be shaped of, for example, a circle, a rectangle, or a line, but aspects of the present disclosure are not limited thereto. As described above, the seed layer 111c may be exposed to the outside through the trace opening 150a and the bump pad opening 150b. The bump pad opening 150b may, for example, correspond to any of the bump pad shapes discussed herein.

Here, the photoresist resin 150 may be in the form of, for example, a liquid or a dry film, but aspects of the present disclosure are not limited thereto.

As illustrated in FIG. 4B, a conductive trace 112 and a conductive bump pad 113′ may be formed on the trace opening 150a and the bump pad opening 150b by a first plating process. Here, the conductive trace 112 and the conductive bump pad 113′ may have the same thickness by a plating time and a concentration of a plating solution. Since the bump pad opening 150b has a larger width than the trace opening 150a, a width of the conductive bump pad 113′ may be larger than that of the conductive trace 112.

In addition, thicknesses (or heights) of the conductive trace 112 and the conductive bump pad 113′ may be smaller than those of the trace opening 150a and the bump pad opening 150b.

As illustrated in FIG. 4C, the trace opening 150a may be blocked by the photoresist resin 150. Accordingly, the conductive trace 112 is completely isolated from the outside. However, the conductive bump pad 113′ is not isolated from the outside. That is to say, the conductive bump pad 113′ is still exposed to the outside through the bump pad opening 150b.

As illustrated in FIG. 4D, the conductive bump pad 113 is formed by a second plating process. That is to say, as the result of the second plating process, only the thickness of the conductive bump pad 113 is increased. In other words, since the conductive trace 112 receives a current and is unable to approach the plating solution while the conductive bump pad 113′ receives a current and is able to approach the plating solution, only the thickness (or height) of the conductive bump pad 113 is eventually increased. That is to say, the conductive trace 112 has a smaller final thickness than the conductive bump pad 113. Since in an example implementation, the conductive bump pad 113 is formed (e.g., plated, etc.) in two stages in the same opening 150b, the lateral surface(s) of the conductive bump pad 113 may be continuous (e.g., without a noticeable discontinuity between the first formed portion and the second formed portion.

Here, as discussed herein, the top surface of the conductive bump pad 113 may be concavely or convexly formed by varying concentrations of the plating solution at a terminal stage of the second plating process.

As illustrated in FIG. 4E, the photoresist resin 150 is completely removed, thereby exposing the conductive trace 112 and the conductive bump pad 113 having different thicknesses and/or widths to the outside. Such removal of the photoresist resin 150 exposes various portions of the seed layer 111c (e.g., portions of the seed layer 111c that are not under the conductive traces 112 or the conductive bump pads 113) to the outside. Soft etching is then performed, thereby removing the seed layer 111c positioned at exterior sides of the conductive trace 112 and the conductive bump pad 113. Accordingly, the first surface 111a of the dielectric layer 111 positioned at the exterior sides of the conductive trace 112 and the conductive bump pad 113 is directly exposed to the outside.

As illustrated in FIG. 4F, since the protection layer 114 is formed on the first surface 111a of the dielectric layer 111, the conductive trace 112 and the conductive bump pad 113 are covered by the protection layer 114, while exposing and/or protruding the top surface of the conductive bump pad 113 to the outside. That is to say, while the protection layer 114 has a larger thickness than the conductive trace 112, it is controlled to have a smaller thickness than the conductive bump pad 113, thereby exposing and/or protruding the top surface and side surfaces (or upper portions thereof) of the conductive bump pad 113 to the outside. Therefore, the conductive trace 112 is completely covered by the protection layer 114, and the top surface and side surfaces (or upper portions thereof) of the conductive bump pad 113 are exposed and/or protruded from the protection layer 114 to the outside. Here, the top surface of the conductive bump pad 113 is completely exposed to the outside, while some portions of the side surfaces (or upper portions thereof) of the conductive bump pad 113 are exposed to the outside.

The protection layer 114 may be formed by any of a variety of processes (e.g., spin coating, printing, spray coating, sintering, thermal oxidation, physical vapor deposition (PVD), sputtering, chemical vapor deposition (CVD), atomic layer deposition (ALD), or the like), but aspects of the present disclosure are not limited thereto.

As illustrated in FIG. 4G, the semiconductor die 120 is electrically connected to the conductive bump pad 113 provided in the substrate 110. The conductive bump 122 including, for example, the conductive pillar 123 and the solder 124, may be formed on the semiconductor die 120. The conductive bump 122 may be electrically connected to the conductive bump pad 113. The conductive bump 122 may be electrically connected to the conductive bump pad 113 by, for example, mass reflowing, thermal compression or laser assisted bonding, but the scope of this disclosure is not limited thereto. In some instances, a non-conductive paste (NCP) may be coated on the conductive bump pad 113 and around the conductive bump pad 113, and the conductive bump 122 of the semiconductor die 120 may be electrically connected to the conductive bump pad 113 of the substrate 110 while passing through the NCP. As described above, the conductive pillar 123 of the semiconductor die 120 may be directly metal-to-metal bonded to the conductive bump pad 113 of the substrate 110 without assistance of a solder.

As illustrated in FIG. 4H, the semiconductor die 120 is encapsulated by, for example, an encapsulant, thereby forming the encapsulation member 130. Here, the encapsulation member 130 may also fill a gap between the substrate 110 and the semiconductor die 120. Alternatively, after an underfill is filled into the gap between the semiconductor die 120 and the substrate 110, the encapsulation member 130 may be formed at exterior sides of the semiconductor die 120 and the substrate 110. The encapsulation member 130 may be formed by, for example, compression molding (that is, using a liquid, powder and/or a film) or vacuum molding. In addition, the encapsulation member 130 may be formed by, for example, transfer molding, but the scope of the present disclosure is not limited thereto.

Here, the encapsulation member 130 may be originally formed to cover the top surface of the semiconductor die 120, and the top surface of the encapsulation member 130 and the semiconductor die 120 may be grinded, thereby making the top surface of the encapsulation member 130 coplanar with the top surface of the semiconductor die 120. In some instances, the grinding may not be performed, so that the encapsulation member 130 may cover the top surface of the semiconductor die 120.

In addition, in some instances, after performing the molding through film assisted molding, the top surface of the semiconductor die 120 may be coplanar with the top surface of the encapsulation member 130. That is to say, a flexible film is positioned on a bottom surface of a mold chase covering the semiconductor die 120, and molding is performed on the flexible film in a state in which the flexible film is brought into close contact with the top surface of the semiconductor die 120. After the molding, the top surface of the semiconductor die 120 may be coplanar with the top surface of the encapsulation member 130.

Thereafter, a conductive bump 140 may be formed in a second conductive trace 116 provided on the bottom surface of the substrate 110. That is to say, the conductive bump 140 may be formed in a region of the second conductive trace 116 exposed downwardly by a solder ball or a solder paste. Here, the outside of the region of the second conductive trace 116, where the conductive bump 140 is to be formed, may also be covered by the protection layer 118.

Meanwhile, since the manufacturing process may be performed in the form of a strip or matrix, discrete semiconductor devices 100 can be implemented by a sawing process or a singulating process using laser beam or diamond blade. Eventually, since the encapsulation member 130 and the substrate 110 are cut together, the side surfaces of the encapsulation member 130 may be coplanar with the side surfaces of the substrate 110.

As described above, in the present disclosure, while the conductive trace 112 and the conductive bump pad 113 are formed at the same time during the first plating process, plating is performed only on the conductive bump pad 113 during the second plating process, thereby allowing the conductive bump pad 113 to have a larger thickness (or height) of the conductive trace 112. Therefore, in the present disclosure, it is easy to control (or maintain) a gap between the substrate 110 and the semiconductor die 120. In addition, in the manufacturing process of the present disclosure, the protection layer 114 is controlled to have a larger thickness than the conductive trace 112 and a smaller thickness than the conductive bump pad 113, thereby exposing and/or protruding the conductive bump 122 to the outside through the protection layer 114 while completely covering the conductive trace 112 by the protection layer 114. Accordingly, an electrical short between the conductive trace 112 and the conductive bump 122 can be prevented from occurring in a subsequent process. For example, the electrical short between the conductive bump pad 113 and the conductive trace 112 does not occur by the conductive bump 122 of the semiconductor die 120.

The discussion herein included numerous illustrative figures that showed various portions of an electronic device assembly and method of manufacturing thereof. For illustrative clarity, such figures did not show all aspects of each example assembly. Any of the example assemblies and/or methods provided herein may share any or all characteristics with any or all other assemblies and/or methods provided herein.

In summary, various aspects of this disclosure provide a semiconductor device and a method of manufacturing a semiconductor device. As a non-limiting example, various aspects of this disclosure provide a semiconductor device, and a method of manufacturing thereof, that comprises a substrate including a dielectric layer, at least one conductive trace and conductive bump pad formed on one surface of the dielectric layer, and a protection layer covering the at least one conductive trace and conductive bump pad, the at least one conductive bump pad having one end exposed through the protection layer, and a semiconductor die electrically connected to the conductive bump pad of the substrate. While the foregoing has been described with reference to certain aspects and examples, it will be understood by those skilled in the art that various changes may be made and equivalents may be substituted without departing from the scope of the disclosure. In addition, many modifications may be made to adapt a particular situation or material to the teachings of the disclosure without departing from its scope. Therefore, it is intended that the disclosure not be limited to the particular example(s) disclosed, but that the disclosure will include all examples falling within the scope of the appended claims.

1-11. (canceled)

12. A method of manufacturing a semiconductor device, the method comprising:
forming a mask layer on a surface, wherein the mask layer comprises a trace opening and a bump pad opening through which the surface is exposed, wherein the trace opening and the bump pad opening are separated from each other by a portion of the mask layer;
performing a first plating process through the trace opening and the bump pad opening to form a conductive trace and a first portion of a conductive bump pad, respectively;
filling the trace opening with a masking material;
performing a second plating process through the bump pad opening to form a second portion of the conductive bump pad;
removing the mask layer; and
covering the conductive trace and a portion of the conductive bump pad with a dielectric layer, the conductive bump pad having one end exposed through the dielectric layer.

13. The method of claim 12, wherein the mask layer comprises photoresist material.

14. The method of claim 12, wherein a top side of the conductive bump pad and an upper portion of a lateral side of the conductive bump pad protrude from the dielectric layer, and a lower portion of the lateral side of the conductive bump pad is covered by the dielectric layer.

15. The method of claim 12, wherein a lateral distance between the conductive trace and the conductive bump pad is less than 10 μm.

16. The method of claim 12, comprising attaching a semiconductor die to the conductive bump by, at least in part, attaching a conductive bump of the semiconductor die to the conductive bump pad with solder that covers at least a portion a lateral side of the conductive bump pad.

17. The method of claim 16, wherein the solder contacts the dielectric layer.

18. The method of claim 12, wherein said second plating process comprises plating the conductive bump pad to have a top side that is concave or convex, and the method comprises attaching a conductive bump of a semiconductor die to the top side of conductive bump pad with a direct copper-to-copper bond.

19. A method of manufacturing a semiconductor device, the method comprising:
forming a mask layer, wherein the mask layer comprises a trace opening and a bump pad opening, wherein:
the trace opening exposes a first portion of a seed layer, where the first portion of the seed layer is directly on and directly above a lower dielectric layer; and
the bump pad opening exposes a second portion of the seed layer, where the second portion of the seed layer is directly on and directly above a lower conductive trace;
performing a first plating process through the trace opening and the bump pad opening to form a conductive trace and a first portion of a conductive bump pad, respectively;
filling the trace opening with a masking material; and
performing a second plating process through the bump pad opening to form a second portion of the conductive bump pad.

20. The method of claim 19, comprising forming a dielectric layer that covers lateral and top sides of the conductive trace and covers only a lower portion of a lateral side of the conductive bump pad.

21. The method of claim 20, wherein a top side of the dielectric layer is at a vertical level between a top side of the conductive trace and a top side of the conductive bump pad.

22. The method of claim 19, wherein said performing a first plating process and said performing a second plating process comprise plating with a same metal.

23. The method of claim 19, wherein a lateral distance between the conductive trace and the conductive bump pad is less than 10 μm.

24. The method of claim 19, wherein said performing a second plating process comprises performing the second plating process to form a curved top surface of the second portion of the conductive bump pad.

25. The method of claim 19, comprising forming solder over a top side of the conductive bump pad.

26. The method of claim 19, wherein said second plating process comprises plating the conductive bump pad to have a top side that is concave or convex, and the method comprises attaching a conductive bump of a semiconductor die to the top side of conductive bump pad with a direct copper-to-copper bond.

27. A method of manufacturing a semiconductor device, the method comprising:
forming a mask layer, wherein the mask layer comprises a first bump pad opening, a trace opening and a second bump pad opening, wherein at least a portion of the trace opening is directly between the first and second bump pad openings;
performing a first plating process through the first bump pad opening, the trace opening, and the second bump pad opening to form a first portion of a first bump pad, a trace, and a first portion of a second bump pad, respectively;
performing a second plating process on the first portion of the first bump pad to form a second portion of the first bump pad and on the first portion of the second bump pad to form a second portion of the second bump pad, without performing the second plating process on the trace,
wherein the first bump pad comprises a lateral bump pad surface, and the lateral bump pad surface is continuous at an interface between the first and second portions of the first bump pad.

28. The method of claim 27, wherein:
the trace opening is separated from the first bump pad opening by a first portion of the mask layer;
the trace opening is separated from the second bump pad opening by a second portion of the mask layer;
the trace opening exposes a first portion of a seed layer, wherein the first portion of the seed layer is directly on and directly above a lower dielectric layer;
the first bump pad opening exposes a second portion of the seed layer, where the second portion of the seed layer is directly on and directly above a first lower conductive trace; and
the second bump pad opening exposes a third portion of the seed layer, where the third portion of the seed layer is directly on and directly above a second lower conductive trace.

29. The method of claim 27, wherein said performing the second plating process comprises performing the second plating process in the first and second bump pad openings of the mask layer.

30. The method of claim 27, comprising forming a dielectric layer that covers lateral and top sides of the trace and covers only a lower portion of respective lateral sides of the first and second bump pads.

31. The method of claim 27, wherein a lateral distance between the first bump pad and the second bump pad at most 10 μm.
